(19) United States
(12) Patent Application Publication
(10) Pub. No.: US 2022/0291463 A1
(43) Pub. Date: Sep. 15, 2022

(54) OPTO-ELECTRIC COMPOSITE TRANSMISSION MODULE

(71) Applicant: NITTO DENKO CORPORATION, Osaka (JP)

(72) Inventors: Naoyuki TANAKA, Osaka (JP); Koya OSUKA, Osaka (JP); Seiki TERAJI, Osaka (JP)

(73) Assignee: NITTO DENKO CORPORATION, Osaka (JP)

(21) Appl. No.: 17/633,445

(22) PCT Filed: Aug. 7, 2020
(86) PCT No.: PCT/JP2020/030305

§ 371 Date: Feb. 7, 2022

(30) Foreign Application Priority Data
Aug. 9, 2019 (JP) 2019-147454

(51) Int. Cl. G02B 6/42

(52) U.S. Cl. CPC G02B 6/4284; G02B 6/4281; H01R 12/778

(57) ABSTRACT

An opto-electric composite transmission module includes a printed wiring board, an electrical connector provided on the printed wiring board, and an opto-electric hybrid board which is electrically connected to the printed wiring board via the electrical connector. The opto-electric hybrid board has a long shape. The opto-electric hybrid board includes an opto-electric conversion portion including a flexible wiring board, a metal support layer, and an optical waveguide film in order in a thickness direction, and an electrical connection portion disposed in one end portion in a longitudinal direction of the opto-electric hybrid board and including the flexible wiring board, and the metal support layer and/or the optical waveguide film. The electrical connection portion is inserted into the electrical connector.

### TECHNICAL FIELD

The present invention relates to an opto-electric composite transmission module.

### BACKGROUND ART

Conventionally, an opto-electric conversion module including a flexible printed board and an optical waveguide film in order in a thickness direction has been known.

For example, it has been proposed that a connection portion disposed in one end portion of the opto-electric conversion module consists of a flexible printed board to be inserted into a FPC connector (ref for example, Patent Document 1 below).

### CITATION LIST

### Patent Document

Patent Document 1: Japanese Unexamined Patent Publication No. 2010-010254

### SUMMARY OF THE INVENTION

### Problem to be Solved by the Invention

The flexible printed wiring board described in Patent Document 1 is thin, and has flexibility. Therefore, it cannot be reliably fixed to an insertion hole of the FPC connector, and is therefore has a problem that electrical connection reliability decreases.

The present invention provides an opto-electric composite transmission module having excellent electrical connection reliability between a connection portion and an electrical connector.

### Means for Solving the Problem

The present invention (1) includes an opto-electric composite transmission module including a printed wiring board, an electrical connector provided on the printed wiring board, and an opto-electric hybrid board electrically connected to the printed wiring board via the electrical connector, wherein the opto-electric hybrid board has a long shape, and includes an opto-electric conversion portion including a flexible wiring board, a metal support layer, and an optical waveguide film in order in a thickness direction, and a connection portion disposed in one end portion in a longitudinal direction of the opto-electric hybrid board and including the flexible wiring hoard, and the metal support layer and/or the optical waveguide film; and the connection portion is inserted in the electrical connector.

According to the opto-electric composite transmission module, the connection portion is inserted into the electrical connector, and the connection portion includes the flexible wiring board, and the metal support layer and/or the optical waveguide film. A thickness of the connection portion can be adjusted corresponding to the electrical connector by the metal support layer and/or the optical waveguide film in addition to the flexible wiring board. Also, the flexible wiring board in the connection portion can be supported by the metal support layer and/or the optical waveguide film, and thus, the connection portion can be made rigid. Therefore, the connection portion is inserted into the electrical connector to be reliably fixed. As a result, excellent electrical connection reliability between the opto-electric hybrid board and the printed wiring board via the electrical connector can be achieved.

The present invention (2) includes the opto-electric composite transmission module described in (1), wherein the connection portion includes the metal support layer and the optical waveguide film, and in the connection portion, the optical waveguide film is in contact with the metal support layer.

However, when the optical waveguide film is disposed in the metal support layer via an adhesive layer, since a thickness of the adhesive layer is not easy to control, the thickness of the connection portion is likely to vary.

On the other hand, in the opto-electric composite transmission module, since the optical waveguide film is in direct contact with the metal support layer, the control of the thickness of the connection portion is accurate and easy. Therefore, the above-described excellent electrical connection reliability can be achieved.

### Effect of the Invention

In the opto-electric composite transmission module of the present invention, excellent electrical connection reliability between an opto-electric hybrid board and a printed wiring board via an electrical connector can be achieved.

### BRIEF DESCRIPTION OF THE DRAWINGS

FIG. 1 shows a cross-sectional view along a longitudinal direction of one embodiment (embodiment in which an electrical connection portion includes an optical waveguide film) of an opto-electric composite transmission module of the present invention.

FIG. 2 shows a process cross-sectional view for illustrating a method for producing the opto-electric composite transmission module shown in FIG. 1.

FIG. 3 shows a cross-sectional view of a modified example (embodiment in which an electrical connection portion includes a metal support layer and an optical waveguide film) of the opto-electric composite transmission module shown in FIG. 1.

FIG. 4 shows a cross-sectional view of a modified example (embodiment in which an electrical connection portion includes a metal support layer) of the opto-electric composite transmission module shown in FIG. 1.

FIG. 5 shows a cross-sectional view along a longitudinal direction of a modified example (embodiment in which an opto-electric hybrid board includes a flexible wiring board, a metal support layer, and an optical waveguide film in order toward one side in a thickness direction) of the opto-electric composite transmission module shown in FIG. 1.

FIG. 6 shows a cross-sectional view along a longitudinal direction of a modified example (embodiment in which an opto-electric hybrid board includes a flexible wiring board, a metal support layer, and an optical waveguide film in order toward one side in a thickness direction) of the opto-electric composite transmission module shown in FIG. 3.

FIG. 7 shows a cross-sectional view along a longitudinal direction of a modified example (embodiment in which an opto-electric hybrid board includes a flexible wiring board, a metal support layer, and an optical waveguide film in order toward one side in a thickness direction) of the opto-electric composite transmission module shown in FIG. 4.

### DESCRIPTION OF EMBODIMENTS

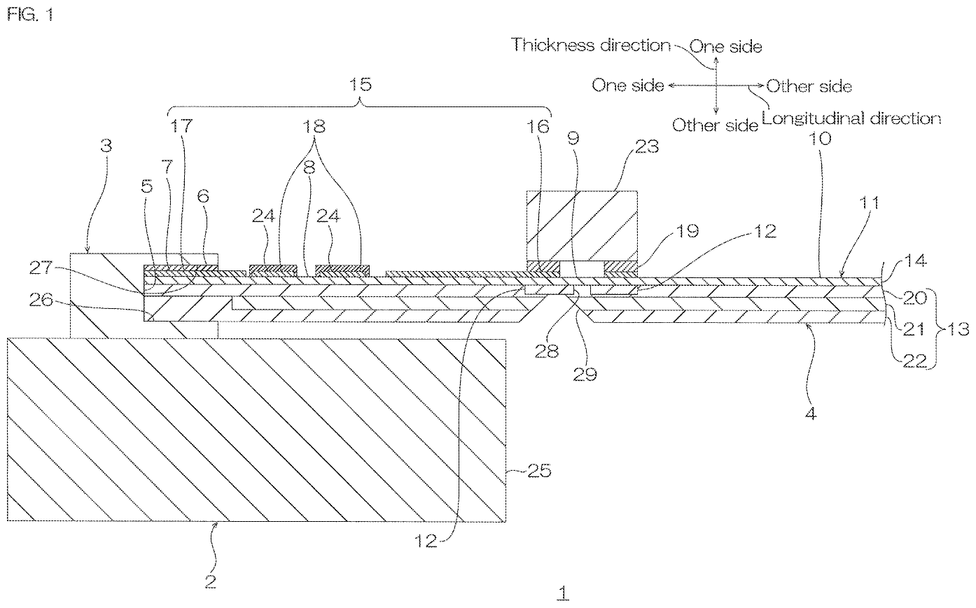

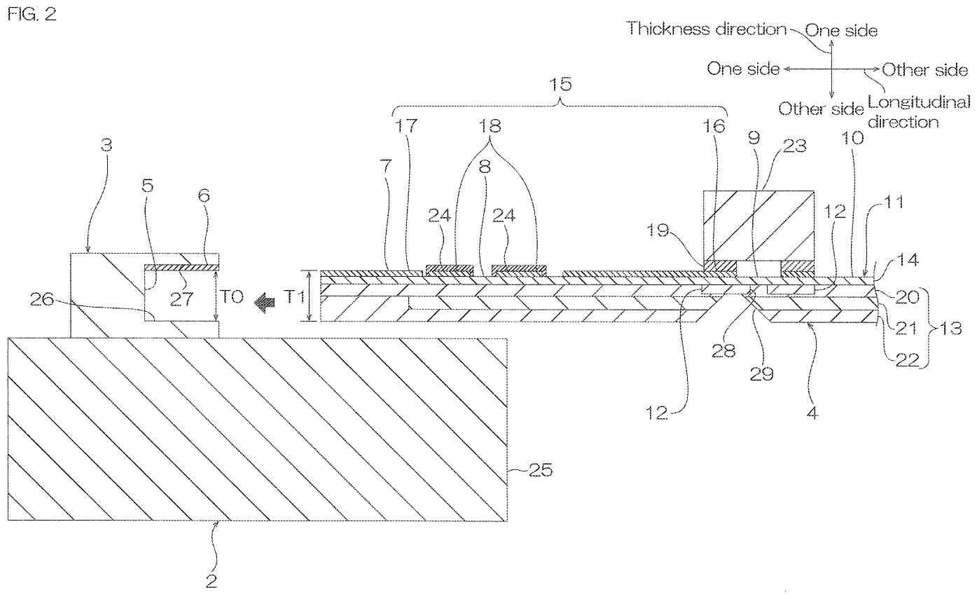

One embodiment of an opto-electric composite transmission module of the present invention is described with reference to FIGS. 1 to 2.

An opto-electric composite transmission module 1 has a long shape. The opto-electric composite transmission module 1 includes a printed wiring board 2, an electrical connector 3, and an opto-electric hybrid board 4.

The printed wiring board 2 is disposed in one end portion in a longitudinal direction of the opto-electric composite transmission module 1. The printed wiring board 2 includes a substrate 25 and a terminal (not shown). The substrate 25 has a fiat plate shape. Examples of a material for the substrate 25 include hard materials such as glass fiber reinforced epoxy resins. The terminal (not shown) is provided on one surface in a thickness direction of the substrate 25 corresponding to the electrical connector 3 to be described next.

Examples of the electrical connector 3 include FPC connectors, ZIF connectors, and connectors for a substrate. The electrical connector 3 is disposed on one surface in the thickness direction of the printed wiring board 2. The electrical connector 3 has, for example, a generally square U-shape (U-shape) in a cross-sectional view. The electrical connector 3 has a insertion port 5 and a connector terminal 6 provided in the insertion port 5.

The insertion port 5 is configured to allow an electrical connection portion 7 (one example of a connection portion) to be described next to be insertable. The insertion port 5 has a first surface 26 and a second surface 27 facing each other in the thickness direction on its inside. The second surface 27 is spaced apart from the first surface 26 at one side in the thickness direction.

The connector terminal 6 is provided on the second surface 27. The connector terminal 6 is provided corresponding to a connector-side terminal 17 (described later) of the electrical connection portion 7.

As shown in FIG. 2, a distance T0 between the first surface 26 and the connector terminal 6 is appropriately set in accordance with a specification (kind) of the electrical connector 3. Specifically, the distance T0 between the first surface 26 and the connector terminal 6 is, for example, 10 μm or more, preferably 100 μm or more, and is, for example, 2,000 μm or less, preferably 500 μm or less.

The opto-electric hybrid board 4 has a long flat plate shape. The opto-electric hybrid board 4 includes the electrical connection portion 7, an electrical transmission portion 8, an opto-electric conversion portion 9, and an optical transmission portion 10 in order in the longitudinal direction. Further, the opto-electric hybrid board 4 includes a flexible wiring board 11, a metal support layer 12, and an optical waveguide film 13.

The electrical connection portion 7 is disposed in one end portion in the longitudinal direction of the opto-electric hybrid board 4. The electrical connection portion 7 includes at least the flexible wiring board 11. Another configuration of the opto-electric hybrid board 4 is described later. The electrical connection portion 7 is inserted into the electrical connector 3, and thus, is electrically connected to the printed wiring board 2 via the electrical connector 3.

The electrical transmission portion 8 is disposed adjacent to the other side in the longitudinal direction of the connector terminal 6. The electrical transmission portion 8 includes the flexible wiring board 11 and the optical waveguide film 13 in order in the thickness direction. On the other hand, the electrical transmission portion 8 does not include the metal support layer 12.

The onto-electric conversion portion 9 is disposed adjacent to the other side in the longitudinal direction of the electrical transmission portion 8. The opto-electric conversion portion 9 includes the flexible wiring board 11, the metal support layer 12, and the optical waveguide film 13 in order in the thickness direction.

The optical transmission portion 10 is disposed adjacent to the other side in the longitudinal direction of the opto-electric conversion portion 9. The optical transmission portion 10 includes the flexible wiring board 11 and the optical waveguide film 13 in order in the thickness direction. On the other hand, the optical transmission portion 10 does not include the metal support layer 12. The other end surface in the longitudinal direction of the optical waveguide film 13 of the optical transmission portion 10 is optically connected to another optical member (optical fiber and the like) which is not shown.

The flexible wiring board 11 is disposed in the entire opto-electric hybrid hoard 4 from one end over the other end of the opto-electric hybrid board 4 in the longitudinal direction. Specifically, the flexible wiring board 11 is disposed in the electrical connection portion 7, the electrical transmission portion 8, the opto-electric conversion portion 9, and the optical transmission portion 10. The flexible wiring board 11 includes a base insulating layer 14, a conductive layer 15, and a cover insulating layer 24.

A shape when viewed from the top of the base insulating layer 14 is the same as that when viewed from the top of the flexible wiring board 11. The base insulating layer 14 is disposed in the electrical connection portion 7, the electrical transmission portion 8, the opts-electric conversion portion 9, and the optical transmission portion 10. Examples of a material for the base insulating layer 14 include insulating materials such as polyimide.

The conductive layer 15 is disposed on one surface in the thickness direction of the base insulating layer 14. The conductive layer 15 is not disposed in the optical transmission portion 10, and is disposed in the electrical connection portion 7, the electrical transmission portion 8, and the opto-electric conversion portion 9. Specifically, the conductive layer 15 includes a conversion-side terminal 16, a connector-side terminal 17, and an electrical wiring 18. The conversion-side terminal 16 is disposed in the opto-electric conversion portion 9. The connector-side terminal 17 is disposed in the electrical connection portion 7. The electrical wiring 18 is disposed in the electrical transmission portion 8. The electrical wiring 18 connects the conversion-side terminal 16 to the connector-side terminal 17. Examples of a material for the conductive layer 15 include conductive materials such as copper.

The cover insulating layer 24 is not disposed in the electrical connection portion 7, the opto-electric conversion portion 9, and the optical transmission portion 10, and is disposed in the electrical transmission portion 8. Specifically, the cover insulating layer 24 is in contact with one surface in the thickness direction of the base insulating layer 14 around the electrical wiring 18 so as to cover the electrical wiring 18. A material for the cover insulating layer 24 is the same as that for the base insulating layer 14.

The flexible wiring board 11 may be provided with an opto-electric conversion element 23 which is mounted on the conversion-side terminal 16. The opto-electric conversion element 23 is electrically connected to the conversion-side terminal 16 via a bonding member 19. The opto-electric conversion element 23 is an element which converts light into electricity or electricity into light.

A thickness of the flexible wiring board 11 in the electrical connection portion 7 is the total thickness of the base insulating layer 14 and the connector-side terminal 17. Specifically, the thickness of the flexible wiring board 11 in the electrical connection portion 7 is, for example, 20 μm or more, preferably 50 μm or more, and is, for example, 250 μm or less, preferably 100 μm or less.

The metal support layer 12 is disposed in an intermediate portion of the opto-electric hybrid board 4 in the longitudinal direction. Specifically, the metal support layer 12 is not disposed in the electrical connection portion 7, the electrical transmission portion 8, and the optical transmission portion 10, and is disposed in the opto-electric conversion portion 9. The metal support layer 12 is disposed on the other surface in the thickness direction of the flexible wiring board 11. Specifically, the metal support layer 12 is in contact with the other surface in the thickness direction of the base insulating layer 14 without an adhesive layer therebetween. The metal support layer 12 has a through hole 28 penetrating in the thickness direction. Examples of a material for the metal support layer 12 include metals such as 42-alloy, aluminum, copper-beryllium, phosphor bronze, copper, and silver. From the viewpoint of ensuring excellent rigidity and toughness, preferably, stainless steel is used.

A thickness of the metal support layer 12 is, for example, 3 μm or more, preferably 10 μm or more, and is, for example, 100 μm or less, preferably 50 μm or less.

The optical waveguide film 13 is disposed at the same position as the flexible wiring board 11 when viewed from the top. The optical waveguide film 13 is disposed in the entire opto-electric hybrid board 4 from one end over the other end of the opto-electric hybrid board 4 in the longitudinal direction. Specifically, the optical waveguide film 13 is disposed over the electrical connection portion 7, the electrical transmission portion 8, the opto-electric conversion portion 9, and the optical transmission portion 10. The optical waveguide film 13 includes an under clad layer 20, a core layer 21, and an over clad layer 22.

The under clad layer 20 is disposed in the electrical connection portion 7, the electrical transmission portion 8, the opto-electric conversion portion 9, and the optical transmission portion 10. The under clad layer 20 is disposed on the other surface in the thickness direction of the base insulating layer 14 of the flexible wiring board 11 so as to be in contact with the other surface in the thickness direction, the outer-side surface, and the inner-side surface (peripheral side surfaces of the through hole 28) of the metal support layer 12.

The core layer 21 is not disposed in the electrical connection portion 7, and is disposed in the electrical transmission portion 8, the opto-electric conversion portion 9, and the optical transmission portion 10. The core layer 21 is disposed on the other surface in the thickness direction of the under clad layer 20. The core layer 21 is formed in a narrower pattern than the under clad layer 20. A mirror 29 is formed in the core layer 21 in the opto-electric conversion portion 9. The mirror 29 faces a light inlet and outlet (not shown) of the opto-electric conversion element 23 in the thickness direction.

The over clad layer 22 is disposed at the same position as the under clad layer 20 when viewed from the top. Specifically, the over clad layer 22 is disposed in the electrical connection portion 7, the electrical transmission portion 8, the opto-electric conversion portion 9, and the optical transmission portion 10. The over clad layer 22 is disposed on the other surface in the thickness direction of the under clad layer 20 so as to cover the other surface in the thickness direction and the side surfaces of the core layer 21.

Examples of a material for the optical waveguide film 13 include transparent and flexible materials such as epoxy resins, acrylic resins, and silicone resins. Preferably, from the viewpoint of optical signal transmissibility, an epoxy resin is used. A refractive index of the core layer 21 is higher than that of the under clad layer 20 and the over clad layer 22.

A thickness of the under clad layer 20 is, for example, 2 μm or more, preferably 10 μm or more, and is, for example, 600 μm or less, preferably 40 μm or less. A thickness of the core layer 21 is, for example, 5 μm or more, preferably 30 μm or more, and is, for example, 100 μm or less, preferably 70 μm or less. A thickness of the over clad layer 22 is, for example, 2 μm or more, preferably 5 μm or more, and is, for example, 600 μm or less, preferably 40 μm or less. The thickness of the over clad layer 22 is a distance between the other surface in the thickness direction of the under clad layer 20 and the other surface in the thickness direction of the over clad layer 22. A ratio of the thickness of the over clad layer 22 to that of the under clad layer 20 is, for example, 1 or more, preferably 2 or more, and is, for example, 10 or less, preferably 5 or less.

The thickness of the optical waveguide film 13 in the electrical connection portion 7 is the total thickness of the under clad layer 20 and the over clad layer 22. The thickness of the optical waveguide film 13 in the electrical connection portion 7 is, for example, 20 μm or more, preferably 50 μm or more, and is, for example, 250 μm or less, preferably 100 μm or less.

Then, in the opto-electric composite transmission module 1, the electrical connection portion 7 includes the optical waveguide film 13 in addition to the flexible wiring board 11. That is, the electrical connection portion 7 does not include the metal support layer 12, and includes the flexible wiring board 11 and the optical waveguide film 13. Preferably, the electrical connection portion 7 consists of the flexible wiring board 11 and the optical waveguide film 13.

The optical waveguide film 13 in the electrical connection portion 7 is disposed on the other surface in the thickness direction of the flexible wiring board 11. Specifically, in the electrical connection portion 7, the optical waveguide film 13 is in contact with the other surface in the thickness direction of the base insulating layer 14 without an adhesive layer therebetween.

Further, the optical waveguide film 13 in the electrical connection portion 7 does not include the core layer 21, and includes the under clad layer 20 and the over clad layer 22. Preferably, the optical waveguide film 13 in the electrical connection portion 7 consists of the under clad layer 20 and the over clad layer 22. Therefore, the optical waveguide film 13 in the electrical connection portion 7 does not optically guide, and functions as a thickness adjusting layer. The thickness adjusting layer can be formed from a common material (material having a higher refractive index than the core layer 21 and common to each other). Therefore, as compared with a case of forming the thickness adjusting layer from a different material, excellent followability with respect to the first surface 26 of the electrical connector 3, and also excellent adhesive properties with respect to the first surface 26 can be achieved.

The optical waveguide film 13 in the electrical transmission portion 8 faces one surface in the thickness direction of the printed wiring board 2.

In one embodiment, as shown in FIG. 2, a thickness T1 of the electrical connection portion 7 is a distance between one surface in the thickness direction of the flexible wiring board 11 and the other surface in the thickness direction of the optical waveguide film 13, and specifically, is a distance between one surface in the thickness direction of the connector-side terminal 17 and the other surface in the thickness direction of the over clad layer 22. Specifically, the thickness T1 of the electrical connection portion 7 is adjusted so as to be substantially the same as the distance T0 between the first surface 26 and the connector terminal 6 in the electrical connector 3.

To produce the opto-electric, composite transmission module 1, as shown in FIG. 2, first, the printed wiring board 2 on which the electrical connector 3 is mounted is prepared.

Separately, the opto-electric hybrid board 4 is prepared. Specifically, first, the metal support layer 12 is prepared, and then, the base insulating layer 14, the conductive layer 15, and the cover insulating layer 24 are provided in order on one surface in the thickness direction of the metal support layer 12. Then, by trimming the outer shape of the metal support layer 12, the through hole 28 is formed. Thereafter, the under clad layer 20, the core layer 21, and the over clad layer 22 are provided (fabricated) in order on the other side in the thickness direction of the metal support layer 12. Thus, the opto-electric hybrid board 4 including the flexible wiring board 11, the metal support layer 12, and the optical waveguide film 13 is prepared. Thereafter, if necessary, the opto-electric conversion element 23 is mounted on the opto-electric conversion portion 9 of the opto-electric hybrid board 4.

Thereafter, the electrical connection portion 7 of the opto-electric hybrid board 4 is inserted into the insertion port 5 of the electrical connector 3. At this time, the connector-side terminal 17 is brought into contact with the connector terminal 6 of the insertion port 5 to be electrically connected thereto. The optical waveguide film 13 is in tight contact with the first surface 26 of the electrical connector 3. Thus, the flexible wiring board 11 of the opto-electric hybrid board 4 and the printed wiring board 2 are electrically connected via the electrical connector 3.

### Function and Effect

Then, according to the opto-electric composite transmission module 1, the electrical connection portion 7 is inserted into the electrical connector 3, and the electrical connection portion 7 includes the flexible wiring board 11 and the optical waveguide film 13. Then, the thickness of the electrical connection portion 7 can be adjusted corresponding to the insertion port 5 of the electrical connector 3 by the optical waveguide film 13 in addition to the flexible wiring board 11. Further, the flexible wiring board 11 in the electrical connection portion 7 can be supported by the optical waveguide film 13, and thus, the electrical connection portion 7 can be made rigid. Therefore, the electrical connection portion 7 is inserted into the insertion port 5 of the electrical connector 3 to be reliably fixed, As a result, excellent electrical connection reliability between the opto-electric hybrid board 4 and the printed wiring board 2 via the electrical connector 3 can be achieved.

### MODIFIED EXAMPLES

In the following each modified example, the same reference numerals are provided for members and steps corresponding to each of those in the above-described one embodiment, and their detailed description is omitted. Further, each modified example can achieve the same function and effect as one embodiment unless otherwise specified. Furthermore, one embodiment and the modified examples thereof can be appropriately used in combination.

Although not shown in FIGS. 1 and 2, the optical waveguide film 13 in the electrical connection portion 7 can also include the core layer 21.

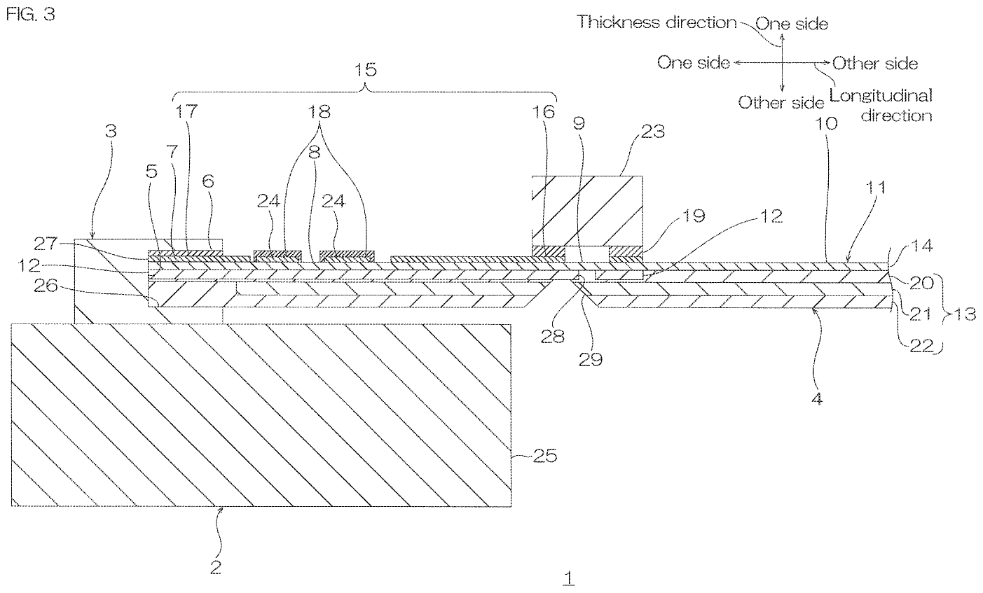

As shown in FIG. 3, the electrical connection portion 7 includes the metal support layer 12 in addition to the flexible wiring board 11 and the optical waveguide film 13. That is, the electrical connection portion 7 includes the flexible wiring board 11, the metal support layer 12, and the optical waveguide film 13. Preferably, the electrical connection portion 7 consists of the flexible wiring board 11, the metal support layer 12, and the optical waveguide film 13. The electrical connection portion 7 includes the flexible wiring board 1 the metal support layer 12, and the optical waveguide film 13 in order toward the other side in the thickness direction. In the electrical connection portion 7, the optical waveguide film 13 is in contact with the other surface in the thickness direction of the metal support layer 12 without an adhesive layer therebetween. The metal support layer 12 in the electrical connection portion 7 functions as the thickness adjusting layer together with the optical waveguide film 13.

According to the modified example shown in FIG. 3, the thickness of the electrical connection portion 7 can be adjusted corresponding to the insertion port 5 of the electrical connector 3 by the metal support layer 12 and the optical waveguide film 13 in addition to the flexible wiring board 11. Further, the flexible wiring board 11 in the electrical connection portion 7 can be supported by the metal support layer 12 and the optical waveguide film 13, and thus, the electrical connection portion 7 can be furthermore made rigid.

The optical waveguide film 13 may be also bonded to the other surface in the thickness direction of the metal support layer 12 via an adhesive layer which is not shown.

Preferably, in the electrical connection portion 7, the optical waveguide film 13 is in contact with the other surface in the thickness direction of the metal support layer 12 without an adhesive layer therebetween.

However, when the optical waveguide film 13 is bonded to the metal support layer 12 via. the adhesive layer, since the thickness of the adhesive layer is not easy to control, the thickness of the electrical connection portion 7 is likely to vary.

On the other hand, in the opto-electric composite transmission module 1 shown in FIG. 3, since in the electrical connection portion 7, the optical waveguide film 13 is in direct contact with the other surface in the thickness direction of the metal support layer 12 without an adhesive layer therebetween, the control of the thickness of the electrical connection portion 7 is accurate and easy. Therefore, the above-described excellent electrical connection reliability can be achieved.

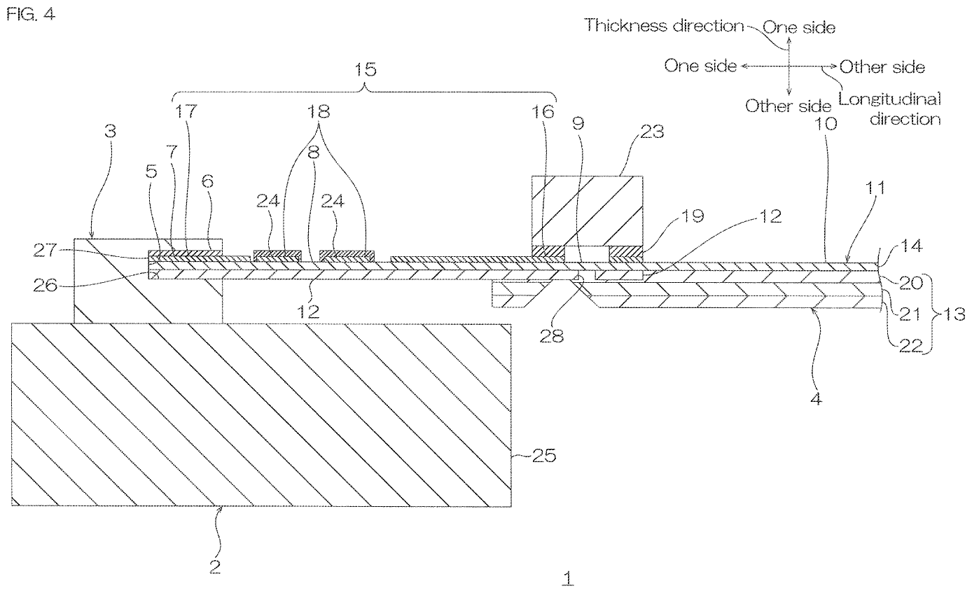

As shown in FIG. 4, the electrical connection portion 7 includes the metal support layer 12 in addition to the flexible wiring board 11. On the other hand, the electrical connection portion 7 does not include the optical waveguide film 13. That is, the electrical connection portion 7 does not include the optical waveguide film 13, and consists of the flexible wiring board 11 and the metal support layer 12. The metal support layer 12 in the electrical connection portion 7 is the thickness adjusting layer.

The optical waveguide film 13 is disposed in the opto-electric conversion portion 9 and the optical transmission portion 10.

According to the modified example shown in FIG. 4, the thickness of the electrical connection portion 7 can be adjusted corresponding to the insertion port 5 of the electrical connector 3 by the metal support layer 12 in addition to the flexible wiring board 11. Further, the flexible wiring board 11 in the electrical connection portion 7 can be supported by the metal support layer 12, and thus, the electrical connection portion 7 can be made rigid.

In view of one embodiment and the modified examples described above, the electrical connection portion 7 includes the flexible wiring board 11, the metal support layer 12 and/or the optical waveguide film 13 as a thickness adjusting layer. Therefore, by the selection and combination of the thickness adjusting layer, it is possible to freely adjust the thickness of the electrical connection portion 7. That is, examples of the above-described thickness adjusting layer include only the metal support layer 12, only the optical waveguide film 13, and a combination of the metal support layer 12 and the optical waveguide film 13.

Also, the present invention includes an embodiment in which the metal support layer 12 and/or the optical waveguide film 13 included in the opto-electric conversion portion 9 are/is extended toward one side in the longitudinal direction until the electrical connection portion 7. Thus, the electrical connection portion 7 includes the metal support layer 12 and/or the optical waveguide film 13 as a thickness adjusting layer.

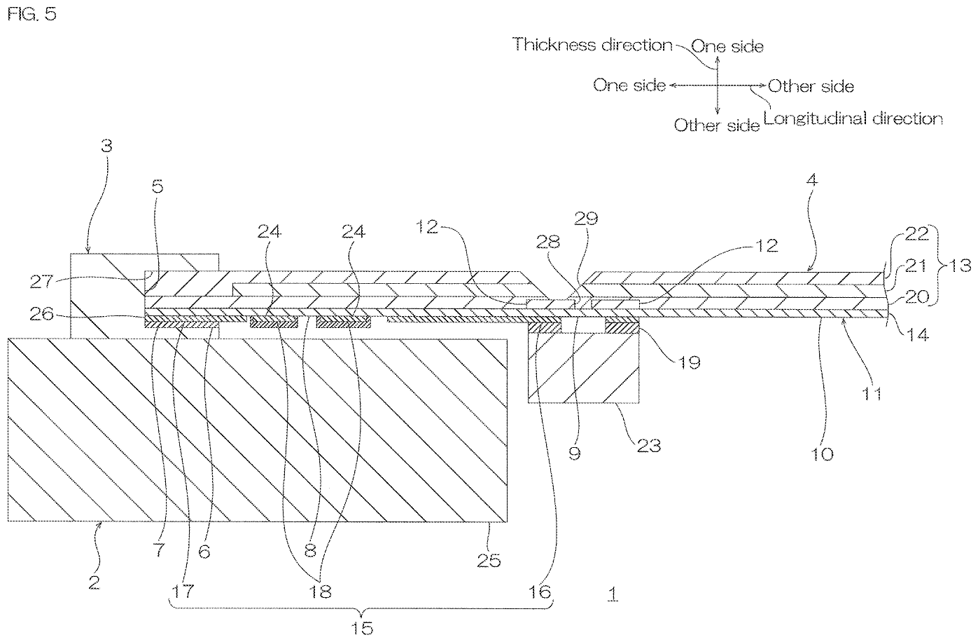

In one embodiment, the opto-electric hybrid board 4 includes the flexible wiring board 11, the metal support layer 12, and the optical waveguide film 13 in order toward the other side in the thickness direction. However, as shown in FIGS. 5 to 7, the opto-electric hybrid board 4 may also include the flexible wiring board 11, the metal support layer 12, and the optical waveguide film 13 in order toward one side in the thickness direction.

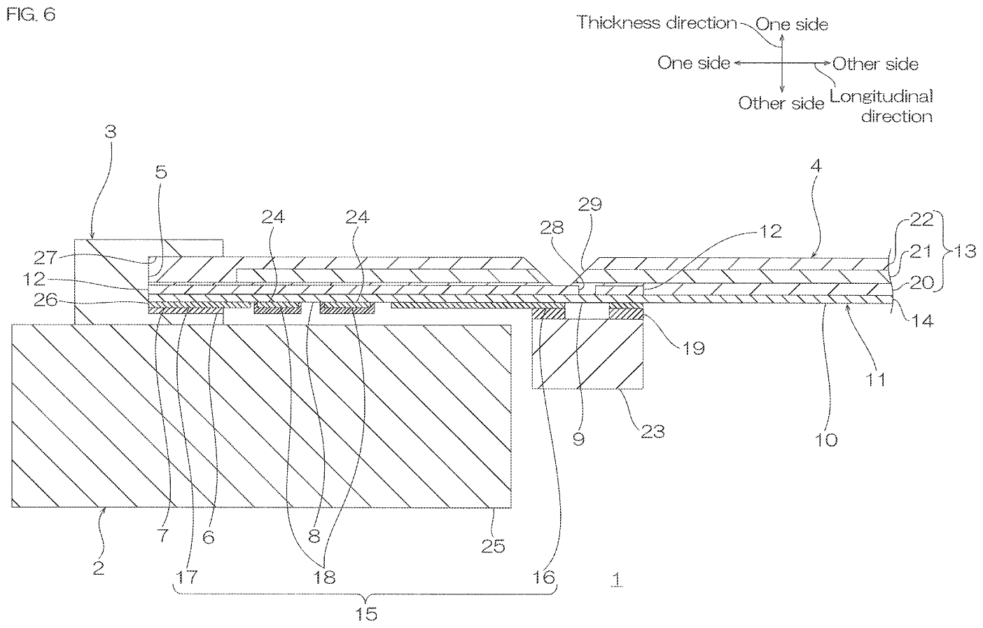

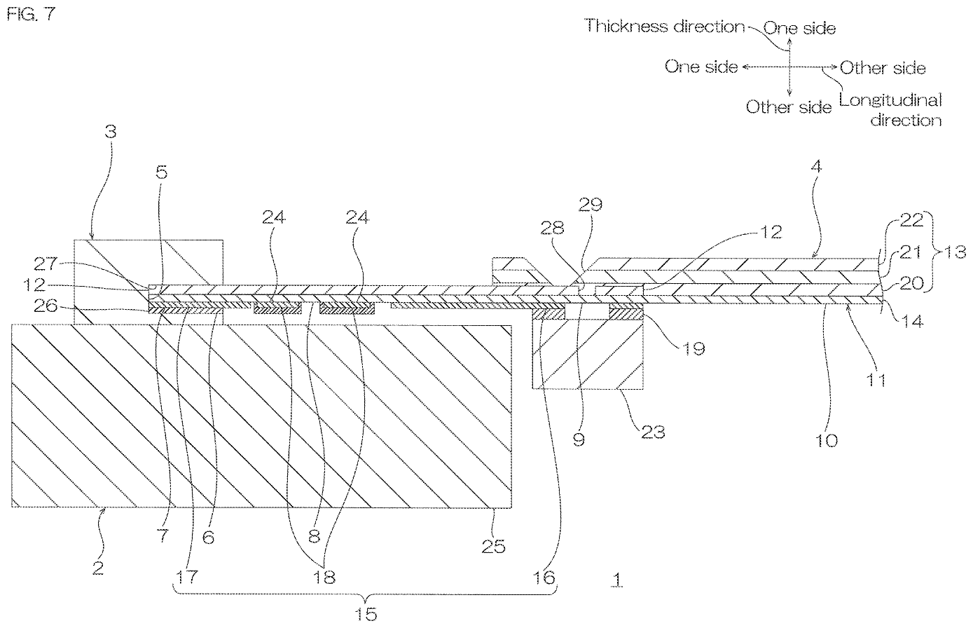

In the modified example shown in FIG. 5, a layer configuration of the opto-electric hybrid board 4 in the opto-electric composite transmission module 1 shown in FIG. 1 is inverted in the thickness direction. In the modified example shown in FIG. 6, a layer configuration of the opto-electric hybrid board 4 in the opto-electric composite transmission module 1 shown in FIG. 3 is inverted in the thickness direction. In the modified example shown in FIG. 7, a layer configuration of the opto-electric hybrid board 4 in the opto-electric composite transmission module I shown in FIG. 4 is inverted in the thickness direction.

In any modified example of FIGS. 5 to 7, the connector terminal 6 is provided on the first surface 26. The flexible wiring board 11 in the electrical transmission portion 8 faces one surface in the thickness direction of the printed wiring board 2.

In the modified examples shown in FIGS. 5 and 6, the optical waveguide film 13 is in tight contact with the second surface 27. In the modified example shown in FIG. 7, the metal support layer 12 is in tight contact with the second surface 27.

While the illustrative embodiments of the present invention are provided in the above description, such is for illustrative purpose only and it is not to be construed as limiting the scope of the present invention. Modification and variation of the present invention that will be obvious to those skilled in the art is to be covered by the following claims.

### INDUSTRIAL APPLICATION

The opto-electric composite transmission module of the present invention is used for various applications.

### DESCRIPTION OF REFERENCE NUMERALS

1 Opto-electric composite transmission module

2 Printed wiring board

3 Electrical connector

4 Opto-electric hybrid board

7 Electrical connection portion

9 Opto-electric conversion portion

11 Flexible wiring board

12 Metal support layer

13 Optical waveguide film

1. An opto-electric composite transmission module comprising:
a printed wiring board,
an electrical connector provided on the printed wiring board, and
an opto-electric hybrid board electrically connected to the printed wiring board via the electrical connector, wherein
the opto-electric hybrid board has a long shape, and includes
an opto-electric conversion portion including a flexible wiring board, a metal support layer, and an optical waveguide film in order in a thickness direction, and
a connection portion disposed in one end portion in a longitudinal direction of the opto-electric hybrid board and including the flexible wiring board, and the metal support layer and/or the optical waveguide film; and
the connection portion is inserted in the electrical connector.

2. The opto-electric composite transmission module according to claim 1, wherein
the connection portion includes the metal support layer and the optical waveguide film, and
in the connection portion, the optical waveguide film is in contact with the metal support layer.
